(19) United States
(12) Patent Application Publication
(10) Pub. No.: US 2026/0077444 A1
(43) Pub. Date: Mar. 19, 2026

(54) METHOD OF MANUFACTURING SEMICONDUCTOR DEVICE AND SEMICONDUCTOR MANUFACTURING APPARATUS

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Yuichiro TANAKA, Hakusan Ishikawa (JP)

(21) Appl. No.: 19/043,954

(22) Filed: Feb. 3, 2025

(30) Foreign Application Priority Data
Sep. 18, 2024 (JP) 2024-161488

(51) Int. Cl. B24B 9/06; H01L 21/67

(52) U.S. Cl. CPC B24B 9/065; H10P 72/0428

(57) ABSTRACT

A method of manufacturing a semiconductor device, according to an embodiment, includes: bonding a semiconductor substrate having a first surface including a pattern region in which a device pattern is provided, a second surface opposite to the first surface, and a bevel portion located on the periphery of the first surface and the second surface, and an adhesive layer formed continuously on the first surface and the bevel portion, to a support substrate having a third surface including a release layer region in which a release layer is formed, so that the first surface and the third surface are bonded via the adhesive layer; and removing at least the bevel portion and a portion of the adhesive layer formed in the bevel portion from the semiconductor substrate, in a state the semiconductor substrate and the support substrate are bonded together with the adhesive layer.

### CROSS-REFERENCE TO RELATED APPLICATIONS

This application is based upon and claims the benefit of priority from the prior Japanese Patent Application No. 2024-161488, filed on Sep. 18, 2024 the entire contents of which are incorporated herein by reference.

### FIELD

The present invention relates to a method of manufacturing a semiconductor device and a semiconductor manufacturing apparatus.

### BACKGROUND

As a technology to support the thinning of semiconductor wafers, a method of manufacturing semiconductor devices has been proposed in which a glass substrate, which serves as a support substrate, and a semiconductor wafer, which serves as a semiconductor substrate, are bonded together via an adhesive layer made of adhesive.

In this conventional method of manufacturing semiconductor devices, the adhesive adhering to the beveled portion of the periphery of the semiconductor wafer may peel off in whisker-like form, for example, when the back surface of the semiconductor wafer is ground in the thinning process after bonding. The adhesive that peels off in this way may remain inside the semiconductor manufacturing apparatus and may cause problems such as accumulating on the filters of the circulation system.

### BRIEF DESCRIPTION OF THE DRAWINGS

FIG. 1 is a diagram showing an example of the configuration of a semiconductor manufacturing apparatus according to an embodiment.

FIG. 2 is a cross-sectional view showing an example of a laminated structure in which a semiconductor wafer processed by the semiconductor manufacturing apparatus shown in FIG. 1 is laminated to a support substrate.

FIG. 3 is a cross-sectional view showing an example of a process for forming a device pattern on a semiconductor wafer in the method of manufacturing semiconductor device according to an embodiment.

FIG. 4 is a cross-sectional view showing an example of a process for forming a release layer on a support substrate in the method of manufacturing semiconductor device according to an embodiment.

FIG. 5 is a cross-sectional view showing an example of a lamination process for laminating a semiconductor wafer and a support substrate in the method of manufacturing semiconductor device according to an embodiment.

FIG. 6 is a cross-sectional view showing an example of a process for trimming a region including a bevel portion of a semiconductor wafer in the method of manufacturing semiconductor device according to an embodiment.

FIG. 7 is a cross-sectional view showing an example of a process for trimming a region including a bevel portion of a semiconductor wafer in the method of manufacturing semiconductor device according to an embodiment, subsequent to FIG. 6.

FIG. 8 is a cross-sectional view showing an example of an end of a structure in which a semiconductor wafer and a support substrate are laminated with an adhesive after the trimming process shown in FIG. 7 is completed.

FIG. 9 is a diagram showing an example of a process flow of a method of manufacturing a semiconductor device according to an embodiment.

FIG. 10 is a cross-sectional view showing an example of a process of trimming a region including a bevel portion of a semiconductor wafer in a method of manufacturing a semiconductor device according to a first modification.

FIG. 11 is a cross-sectional view showing an example of a process of trimming a region including a bevel portion of a semiconductor wafer in a method of manufacturing a semiconductor device according to a second modification.

FIG. 12 is a cross-sectional view showing an example of a process of trimming a region including a bevel portion of a semiconductor wafer in a method of manufacturing a semiconductor device according to a third modification.

### DETAILED DESCRIPTION

An object of one embodiment is to provide a method of manufacturing semiconductor devices and a semiconductor manufacturing apparatus that can suppress peeling of peripheral portions of an adhesive that bonds a semiconductor substrate and a support substrate together during the manufacturing process of the semiconductor device.

A method of manufacturing a semiconductor device, according to an embodiment, includes: bonding a semiconductor substrate having a first surface including a pattern region in which a device pattern is provided, a second surface opposite to the first surface, and a bevel portion located on the periphery of the first surface and the second surface, and an adhesive layer formed continuously on the first surface and the bevel portion, to a support substrate having a third surface including a release layer region in which a release layer is formed, so that the first surface and the third surface are bonded via the adhesive layer; and removing at least the bevel portion and a portion of the adhesive layer formed in the bevel portion from the semiconductor substrate, in a state the semiconductor substrate and the support substrate are bonded together with the adhesive layer.

Hereinafter, a semiconductor manufacturing apparatus and a method of manufacturing semiconductor devices according to embodiments will be described in detail with reference to the accompanying drawings. It is noted that the present invention is not limited to these embodiments.

### Embodiment

As described above, the method of manufacturing semiconductor devices includes a thinning process in which a semiconductor substrate is attached to a thick support substrate with an adhesive and then ground. By attaching the semiconductor substrate to a thick support substrate, the flatness of the semiconductor wafer can be maintained at a good level during trimming, and the semiconductor wafer can be uniformly thinned. The thinned semiconductor substrate is subjected to required processing such as circuit pattern formation on the trimming surface while still attached to the support substrate, and then peeled off from the support substrate and diced into chips. In this embodiment, an example of a configuration including a semiconductor manufacturing apparatus used in the thinning process for thinning a semiconductor substrate and a semiconductor substrate to be ground, which are among the processes for manufacturing semiconductor devices, is described, and an example of a method of manufacturing semiconductor devices using this semiconductor manufacturing apparatus is also described.

### Semiconductor Manufacturing Apparatus

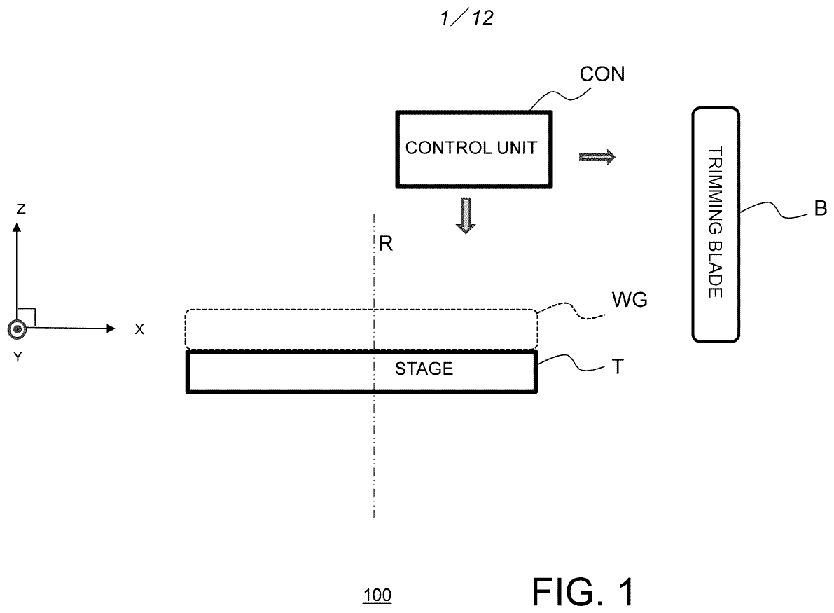

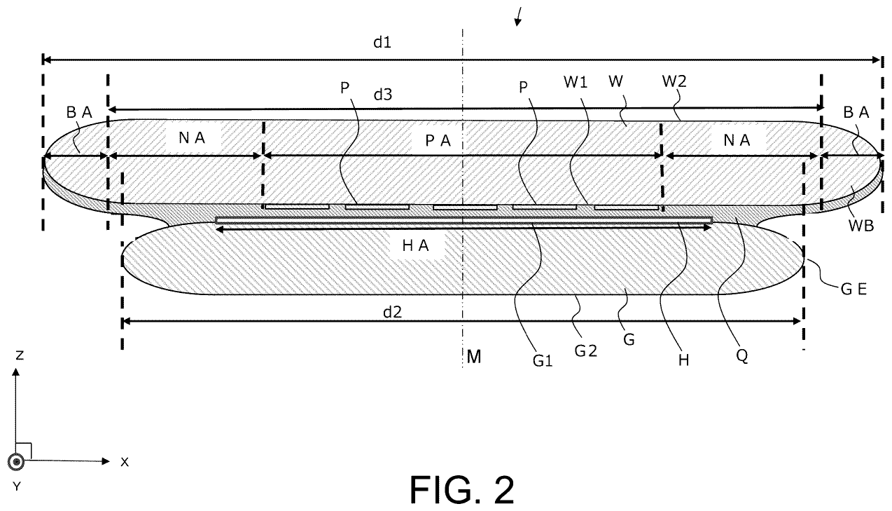

FIG. 1 is a diagram showing an example of the configuration of a semiconductor manufacturing apparatus according to an embodiment. The semiconductor manufacturing apparatus 100 shown in FIG. 1 is an apparatus used in the process of manufacturing a semiconductor device, particularly in the thinning process of thinning a semiconductor substrate W. FIG. 2 is a cross-sectional view showing an example of a bonding structure in which a semiconductor wafer processed by the semiconductor manufacturing apparatus shown in FIG. 1 is bonded to a support substrate.

For example, as shown in FIG. 1, the semiconductor manufacturing apparatus 100 includes a stage T, a trimming blade B, and a control unit CON.

### Stage

The stage T is a rotating means for fixing and rotating the bonded structure WG (FIG. 2) which is formed by bonding a semiconductor substrate W and a support substrate G described below. The stage T is configured to fix the semiconductor substrate W or the support substrate G of the bonded structure WG by suction or the like. The stage T rotates around a rotation axis R parallel to the Z direction, for example, as shown in FIG. 1, thereby rotating the bonded structure WG fixed to the upper surface of the stage T which is parallel to the X and Y directions, around the rotation axis R.

### Trimming Blade

The trimming blade B is a trimming means for trimming the end of the bonded structure WG.

### Control Unit

The control unit CON is a control means that controls the rotational operation of the stage T, as well as the displacement and trimming operation of the trimming blade B.

With the bonded structure WG placed on the stage T, the control unit CON controls the rotational operation of the stage T as well as the displacement and trimming operation of the trimming blade, so that at least the bevel portion WB and the portion of the adhesive layer Q formed on the bevel portion WB shown in FIG. 2 are removed from the semiconductor substrate W, by trimming at least the bevel portion WB and the portion of the adhesive layer Q with the trimming blade.

### Bonded Structure

Here, with particular reference to FIG. 2, an example of the detailed configuration of a bonded structure WG in which a semiconductor substrate W and a support substrate G are bonded together, which is processed by the semiconductor manufacturing apparatus 100 as described above, will be described.

As shown in FIG. 2, the bonded structure WG includes, for example, a semiconductor substrate W, a support substrate G, and an adhesive layer Q. This bonded structure WG is constructed by bonding the semiconductor substrate W and the support substrate G together so that they are bonded via the adhesive layer Q.

### Semiconductor Substrate

The semiconductor substrate W is, for example, a semiconductor wafer. The material of this semiconductor substrate W is, for example, a semiconductor material such as silicon, sapphire, GaAs (gallium arsenide), etc.

As shown in FIG. 2, the semiconductor substrate W has a first surface (front side) W1 which is a main surface including a pattern area PA in which a device pattern P of a semiconductor element or the like is provided, a second surface (back side) W2 which is a main surface opposite the first surface W1, and a bevel portion WB located on the periphery of the first surface W1 and the second surface W2.

Then, for example, as shown in FIG. 2, an adhesive layer Q is continuously formed on the first surface W1 and bevel portion WB including the pattern area PA and non-pattern forming area NA of the semiconductor substrate W. In particular, the device pattern P in the pattern area PA is covered by the adhesive layer Q on the first surface of the semiconductor substrate W.

The non-pattern-formation area NA is located between the outer periphery of the pattern area PA of the semiconductor substrate W and the area BA of the bevel portion WB, for example, as shown in FIG. 2. This non-pattern-formation area NA is an area in which a device pattern P of a semiconductor element or the like is not formed.

### Adhesive Layer

As described above, the adhesive layer Q is continuously formed on the first surface W1 and the bevel portion WB of the semiconductor substrate W, as shown in FIG. 2.

The material for this adhesive layer Q is an adhesive that is soluble in an organic solvent and whose main component is, for example, an acrylic resin, a hydrocarbon resin (polycycloolefin resin, terpene resin, petroleum resin, etc.), a novolac-type phenolic resin, etc. The adhesive layer Q is formed by applying such an adhesive to the surface of the semiconductor substrate W.

The bonded structure WG is constructed by bonding the first surface W1 of the semiconductor substrate W and the third surface G1 of the support substrate G together via an adhesive layer Q.

### Support Substrate

The support substrate G has the function of reinforcing and complementing the mechanical strength of the semiconductor substrate W and maintaining the flatness of the semiconductor substrate W when the semiconductor substrate W is processed, such as thinned or when a circuit pattern is formed, or when the semiconductor substrate W is transported for processing.

This support substrate G is, for example, a glass substrate. However, the material of this support substrate G is not limited to glass, and may be, for example, silicon, alumina, silicon carbide, aluminum, stainless steel, resin, etc. Furthermore, the shape of the support substrate G is determined appropriately according to the shape of the semiconductor substrate W to be supported. Furthermore, the thickness of the support substrate G is determined appropriately depending on the material, the required strength, etc.

As shown in FIG. 2, for example, this support substrate G has a third surface (front surface) G1 which is a main surface including a release layer area HA in which a release layer H is formed, a fourth surface (back surface) G2 which is a main surface opposite the third surface G1, and an end portion GE located on the periphery of the third surface G1 and the fourth surface G2.

### Peel Layer

The peel layer area HA in the center of the third surface G1 of the support substrate G is provided with a peel layer H made of a non-peelable resin or the like that does not exhibit adhesive properties with respect to the adhesive layer Q.

It is preferable that this peeling layer H be formed over as large an area as possible so that the semiconductor substrate W, which is bonded to the surface of the support substrate G by the adhesive layer Q, does not peel off during processing such as thinning or during transportation.

In particular, as shown in FIG. 2, the semiconductor substrate W and the support substrate G are bonded together so that the entire pattern area PA on the first surface W1 of the semiconductor substrate W, in which the device pattern P is provided, faces the release layer area HA on the third surface G1 of the support substrate G, in which the release layer H is formed.

Here, as already described, as shown in FIG. 2, the bonded structure WG is formed by bonding the first surface W1 of the semiconductor substrate W and the third surface G1 of the support substrate G together via an adhesive layer Q.

In particular, as shown in FIG. 2, the semiconductor substrate W and the supporting substrate G are bonded together so that a perpendicular line M, that passes through the center of the first surface W1 of the semiconductor substrate W and is parallel to the Z direction of the first surface W1, passes through the center of the third surface G1 of the supporting substrate G. The range defined as the perpendicular line M passing through the center of the third surface G1 of the supporting substrate G is a range that allows for a deviation of, for example, several tens of microns from the desired bonding position of the semiconductor substrate W and the supporting substrate G. When the bonded structure WG is subjected to a trimming process by the semiconductor manufacturing apparatus 100 shown in FIG. 1 described above, the bonded structure WG is placed on the stage T so that the perpendicular line M overlaps with the rotation axis R of the stage T.

Furthermore, as shown in FIG. 2, in the bonded structure WG, the semiconductor substrate W has an average diameter of a first value d1 in a direction (X direction) parallel to the first surface W1 of the semiconductor substrate W. The supporting substrate G has an average diameter of a second value d2 in a direction (X direction) parallel to the third surface G1 of the supporting substrate G. The first value d1 is set to be larger than the second value d2. The second value d2 is set to be longer than the distance of the pattern area PA of the semiconductor substrate W in a direction (X direction) parallel to the first surface W1 of the semiconductor substrate W.

In other words, in the example shown in FIG. 2, when the semiconductor substrate W and the support substrate G are bonded together with the adhesive layer Q, the peripheral edge GE of the support substrate G is located in an area closer to the peripheral edge of the semiconductor substrate W than the outer periphery of the pattern area PA of the semiconductor substrate W in the direction (X direction) parallel to the first surface W1 when viewed from the direction (Z direction) perpendicular to the first surface W1.

In particular, the average diameter of the area including the non-pattern-forming area NA and the pattern area PA, excluding the bevel portion WB, of the semiconductor substrate W in the direction (X direction) parallel to the first surface W1 of the semiconductor substrate W is a third value d3. The second value d2 described above is set to be smaller than the third value d3.

In other words, when the semiconductor substrate W and the support substrate G are bonded together with the adhesive layer Q, the peripheral end GE of the support substrate G is located in a non-pattern-formed region NA between the outer periphery of the pattern region PA of the semiconductor substrate W and the region BA of the bevel portion WB in the direction (X, Y directions) parallel to the first surface W1 of the semiconductor substrate W, in a plan view in the direction (Z direction) perpendicular to the first surface W1 of the semiconductor substrate W.

### Method of Manufacturing Semiconductor Device

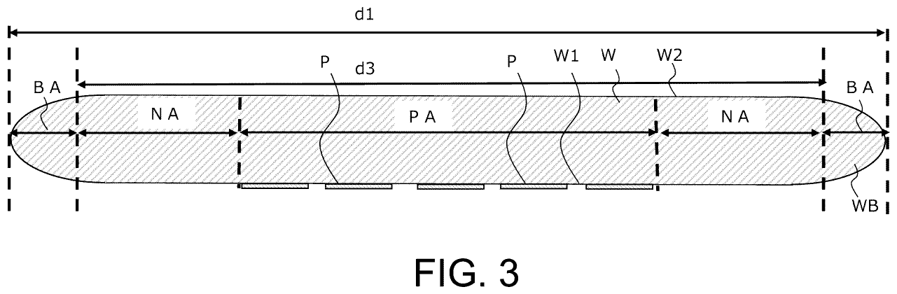

Next, a method of manufacturing semiconductor devices using the semiconductor manufacturing apparatus 100 according to this embodiment will be described with reference to FIGS. 3 to 9, including processing of the bonded structure WG in which the semiconductor substrate W is bonded to the surface of the support substrate G as described above via the adhesive layer Q.

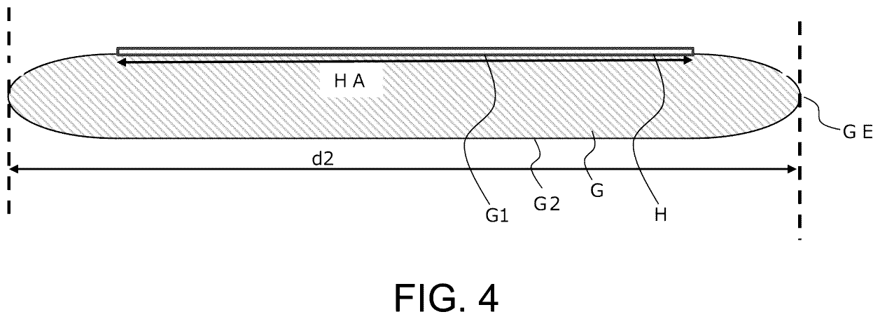

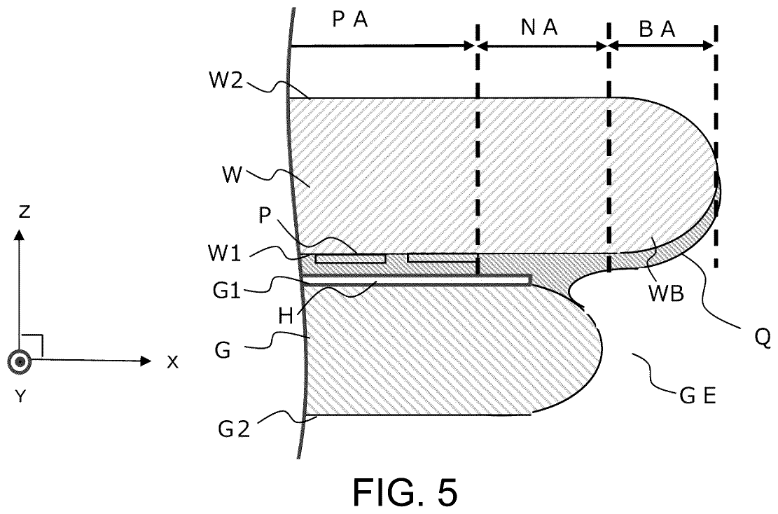

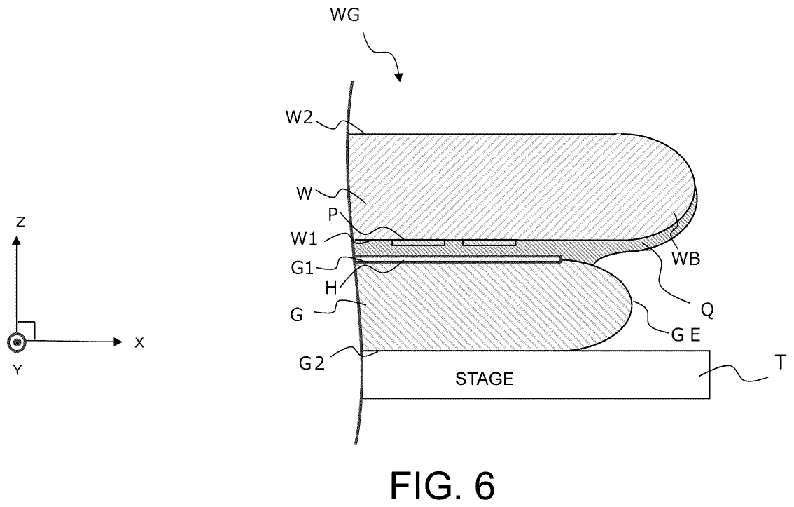

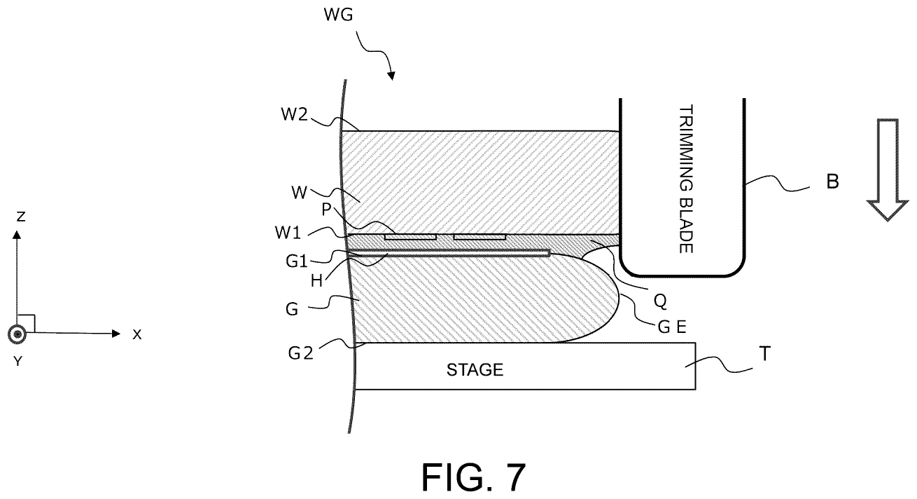

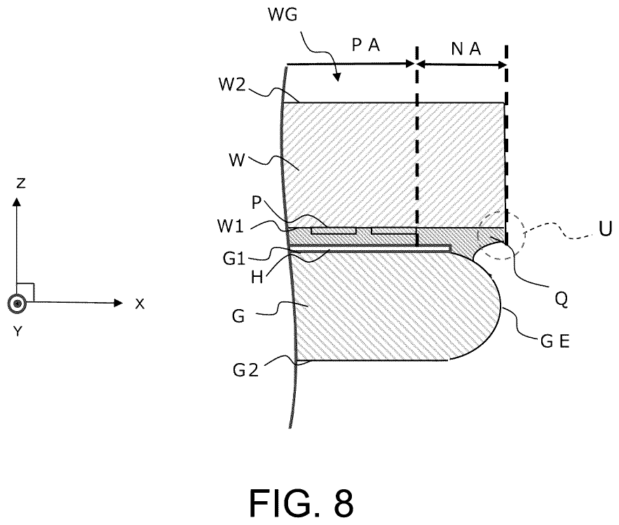

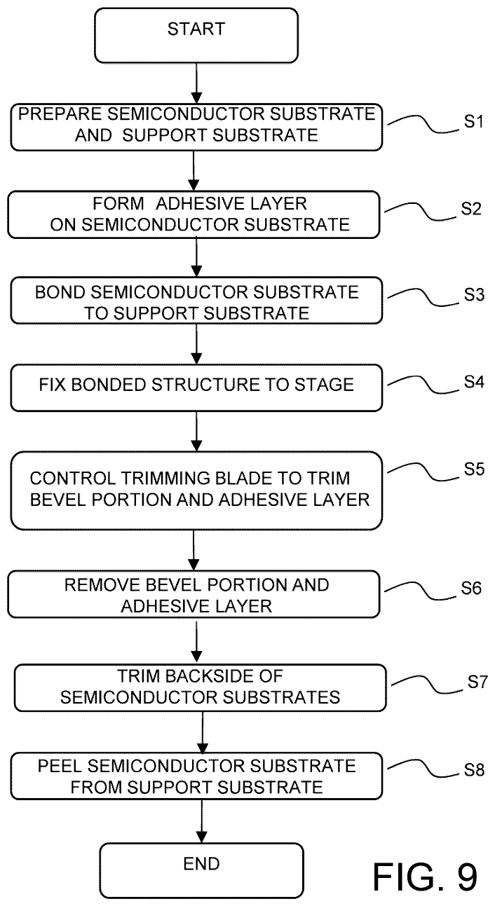

Here, FIG. 3 is a cross-sectional view showing an example of a process for forming a device pattern on a semiconductor wafer in the method of manufacturing semiconductor device according to an embodiment. FIG. 4 is a cross-sectional view showing an example of a process for forming a release layer on a support substrate in the method of manufacturing semiconductor device according to an embodiment. FIG. 5 is a cross-sectional view showing an example of a lamination process for laminating a semiconductor wafer and a support substrate in the method of manufacturing semiconductor device according to an embodiment. FIG. 6 is a cross-sectional view showing an example of a process for trimming a region including a bevel portion of a semiconductor wafer in the method of manufacturing semiconductor device according to an embodiment. FIG. 7 is a cross-sectional view showing an example of a process for trimming a region including a bevel portion of a semiconductor wafer in the method of manufacturing semiconductor device according to an embodiment, subsequent to FIG. 6. FIG. 8 is a cross-sectional view showing an example of an end of a structure in which a semiconductor wafer and a support substrate are laminated with an adhesive after the trimming process shown in FIG. 7 is completed. FIG. 9 is a diagram showing an example of a process flow of a method of manufacturing a semiconductor device according to an embodiment.

First, in a step prior to the thinning step, a device pattern P is formed on a semiconductor substrate W, as shown in FIG. 3, for example. This results in the preparation of a semiconductor substrate W having a first surface W1 which includes a pattern region in which the device pattern P is provided, a second surface W2, and a bevel portion WB (the step S1 in FIG. 9).

On the other hand, for example as shown in FIG. 4, a release layer H is formed on a support substrate G. This results in a support substrate G having a third surface G1 including a release layer area HA where the release layer H is formed, a fourth surface G2, and end portions GE located on the periphery of the third surface G1 and the fourth surface G2 (the step S1 in FIG. 9).

Next, an adhesive layer Q is continuously formed on the first surface W1 and the bevel portion WB of the semiconductor substrate W (the step S2 in FIG. 9). The adhesive that constitutes the adhesive layer Q is applied, for example, using a coating device (not shown) such as a spin coater while rotating the semiconductor substrate W.

Then, for example, as shown in FIG. 5, the semiconductor substrate W having an adhesive layer Q formed continuously on its first surface W1 and bevel portion WB is bonded to a support substrate G having a peeling layer H formed thereon, so that the first surface W1 of the semiconductor substrate W and the third surface G1 of the support substrate G are bonded to each other via the adhesive layer Q (the step S3 in FIG. 9).

As described above, the semiconductor substrate W and the support substrate G are bonded together so that all of the pattern areas PA on the first surface W1 of the semiconductor substrate W, in which the device patterns P are provided, face the release layer areas HA on the third surface G1 of the support substrate G, in which the release layer H is formed.

Next, for example, as shown in FIG. 6, the fourth surface G2 of the support substrate G of the bonded structure WG is fixed to the stage T of the semiconductor manufacturing apparatus 100 (the step S4 in FIG. 9). Then, with the semiconductor substrate W and the support substrate G bonded together by the adhesive layer Q, the control unit CON of the semiconductor manufacturing apparatus 100 controls the rotational operation of the stage T and controls the displacement and trimming operation of the trimming blade B.

In this embodiment, for example, as shown in FIG. 7, with the semiconductor substrate W and support substrate G bonded together by the adhesive layer Q, the support substrate G is fixed to the stage T and rotated while the trimming blade B is displaced from the second surface W2 side toward the first surface W1 side of the semiconductor substrate W. This operation of the stage T and trimming blade B trims at least the bevel portion WB and the portion of the adhesive layer Q formed on the bevel portion WB (the step S5 in FIG. 9).

In particular, with the semiconductor substrate W and the support substrate G bonded together by the adhesive layer Q, at least the bevel portion WB and the portion of the adhesive layer Q formed on the bevel portion WB are removed from the semiconductor substrate W by trimming with the trimming blade B, in one trimming operation of the trimming blade B, i.e., simultaneously.

As shown in FIG. 3, the second value d2 of the average diameter of the support substrate G is set to be smaller than the third value d3 of the average diameter of the region including the non-pattern forming region NA and the pattern region PA excluding the bevel portion WB of the semiconductor substrate W. As a result, as shown in FIG. 7, when the trimming blade B is displaced in the Z direction from the second surface W2 side toward the first surface W1 side of the semiconductor substrate W, it is possible to prevent the trimming blade B from contacting the support substrate G. In other words, it is possible to make it easier to control the trimming blade B. Furthermore, since the support substrate G is not ground by the trimming blade B in this way, it is possible to reuse the support substrate G peeled off from the semiconductor substrate W. Furthermore, since the support substrate G is not ground by the trimming blade B, it is possible to reduce the risk of cutting debris adhering to the stage T.

In this way, for example, as shown in FIG. 8, at least the bevel portion WB and the portion of the adhesive layer Q formed on the bevel portion WB are removed from the semiconductor substrate W by being ground with a trimming blade (the step S6 in FIG. 9).

Therefore, for example, by removing the adhesive layer Q in a position parallel to the second surface W2 of the semiconductor substrate W, which will be the processing surface in the back trimming process described below, the adhesive layer Q will no longer come into contact with the trimming wheel used to trim the back surface. This makes it possible to make the adhesive layer Q less likely to peel off during the back trimming process.

Then, in the subsequent back surface trimming process, the second surface W2 of the semiconductor substrate W of the bonded structure WG is ground with a trimming wheel to thin the semiconductor substrate W (the step S7 in FIG. 9). The thinned semiconductor substrate W is then attached to the support substrate G, and, for example, a damaged layer (fractured layer) caused by wheel trimming (machining) on the ground second surface W2 is removed by wet etching (processing using a chemical reaction), after which the required processing is performed, such as depositing a metal layer that will become the back surface electrode by a method such as sputtering, and the substrate is then peeled off from the support substrate G and subjected to a dicing process to be made into chips (the step S8 in FIG. 9).

As described above, the method of manufacturing semiconductor device can prevent the adhesive attached to the bevel portion of the peripheral edge of the semiconductor substrate from peeling off in whisker-like form, for example, when the back surface of the semiconductor substrate is ground in the thinning process. In this way, by preventing the adhesive layer from peeling off, it is possible to prevent the adhesive from remaining inside the semiconductor manufacturing apparatus and to prevent the adhesive from accumulating on the filter of the circulation system device. In addition, by lining the inside with glass, blade control can be made easier and it is also possible to reduce the risk of glass breakage.

In other words, according to the method of manufacturing semiconductor device according to this embodiment, peeling of the peripheral portion of the adhesive that bonds the semiconductor substrate and the support substrate during the manufacturing process of the semiconductor device can be suppressed.

Here, in the embodiment described above, an example of a manufacturing method step is described in which a trimming blade is used to remove the vicinity of the bevel portion together with part of the adhesive layer in order to prevent peeling of the adhesive layer. However, the method of using a trimming blade to remove the vicinity of the bevel portion together with part of the adhesive layer in order to prevent peeling of the adhesive layer is not limited to the method described in the embodiment. In the following first to third modifications, other examples of the method of using a trimming blade to remove the vicinity of the bevel portion together with part of the adhesive layer in order to prevent peeling of the adhesive layer are described.

### First Modification

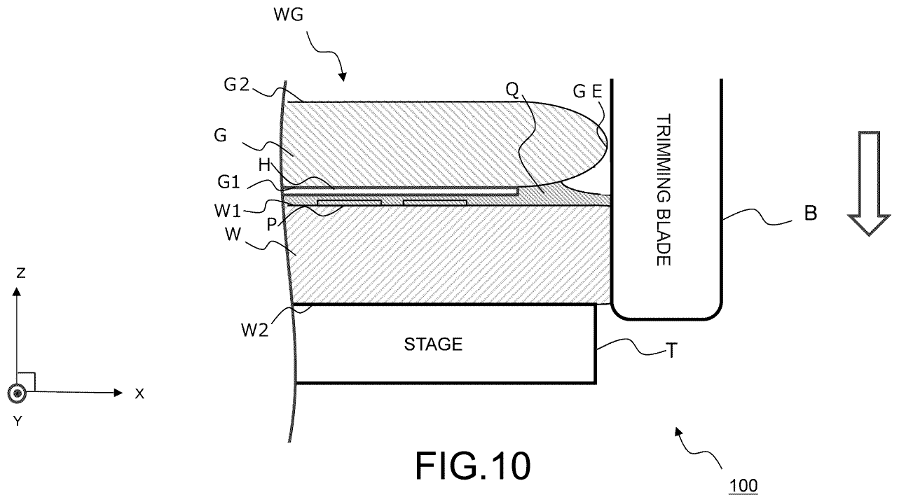

Here, FIG. 10 is a cross-sectional view showing an example of a process for trimming a region including a bevel portion of a semiconductor wafer in a method of manufacturing semiconductor devices according to a first modification. The configuration of the semiconductor manufacturing apparatus according to the first modification is similar to that of the semiconductor manufacturing apparatus 100 shown in FIG. 1 of the embodiment described above.

First, as in the previously described embodiment, a semiconductor substrate W and a support substrate G are prepared by performing the processes shown in FIG. 3 and FIG. 4, for example.

Then, as in the previously described embodiment, an adhesive layer Q is formed continuously on the first surface W1 and bevel portion WB of the semiconductor substrate W. Then, as shown in FIG. 5, the semiconductor substrate W having the adhesive layer Q formed continuously on the first surface W1 and bevel portion WB and a support substrate G having a peeling layer H formed thereon are bonded together so that the first surface W1 of the semiconductor substrate W and the third surface G1 of the support substrate G are bonded together via the adhesive layer Q.

Next, in this first modification, for example, as shown in FIG. 10, the second surface W2 of the semiconductor substrate W of the bonded structure WG is fixed to the stage T of the semiconductor manufacturing apparatus 100. Then, the control unit CON of the semiconductor manufacturing apparatus 100 controls the rotational operation of the stage T while the semiconductor substrate W and the support substrate G are bonded together by the adhesive layer Q, and also controls the displacement and trimming operation of the trimming blade B.

In this first modification, for example, as shown in FIG. 10, in a state in which the semiconductor substrate W and the support substrate G are bonded together with the adhesive layer Q, the trimming blade B is displaced in the Z direction from the first surface W1 side to the second surface W2 side of the semiconductor substrate W while the semiconductor substrate W is fixed to and rotated on the stage T. As a result, at least the bevel portion WB and the portion of the adhesive layer Q formed on the bevel portion WB are ground by the trimming blade.

In the first modification, as shown in FIG. 3, the second value d2 of the average diameter of the support substrate G is set to be smaller than the third value d3 of the average diameter of the region including the non-pattern forming region NA and the pattern region PA excluding the bevel portion WB of the semiconductor substrate W. As a result, as shown in FIG. 10, when the trimming blade B is displaced in the Z direction from the first surface W1 side toward the second surface W2 side of the semiconductor substrate W, it is possible to prevent the trimming blade B from contacting the support substrate G. In other words, it is possible to easily control the trimming blade B.

In this manner, as in the previously described embodiment, as shown in FIG. 8, at least the bevel portion WB and the portion of the adhesive layer Q formed on the bevel portion WB are removed from the semiconductor substrate W by trimming with the trimming blade.

Therefore, in the end region U near the non-pattern formation region NA of the semiconductor substrate W, the end of the adhesive layer Q has a certain thickness greater than the thickness of the adhesive layer Q adhered to the bevel portion WB, thereby preventing the adhesive layer Q from peeling off.

In other words, according to the method of manufacturing semiconductor device of this first modification, as in the previously described embodiment, peeling of the peripheral portion of the adhesive that bonds the semiconductor substrate and the support substrate during the manufacturing process of the semiconductor device can be suppressed.

### Second Modification

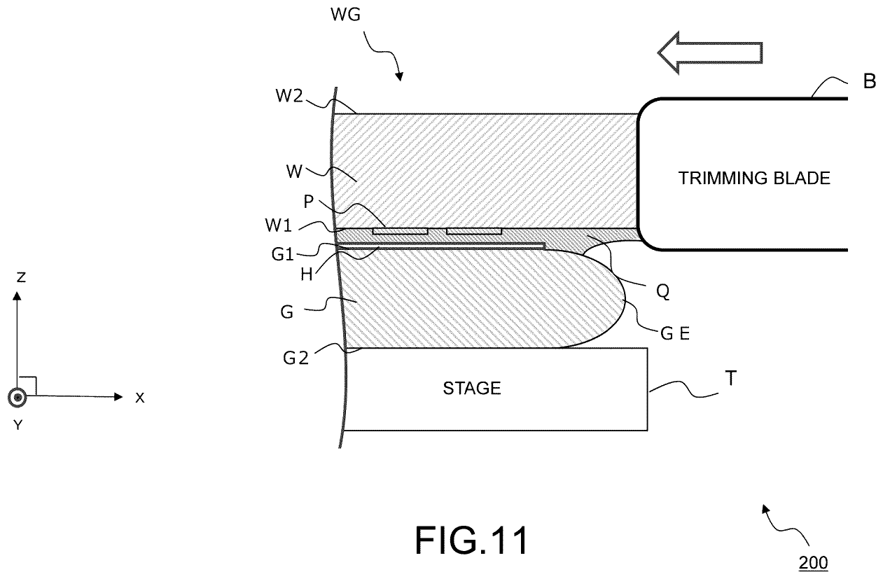

FIG. 11 is a cross-sectional view showing an example of a process for trimming a region including a bevel portion of a semiconductor wafer in a method of manufacturing semiconductor devices according to a second modification. The configuration of the semiconductor manufacturing apparatus 200 according to the second modification is similar to that of the semiconductor manufacturing apparatus 100 shown in FIG. 1 of the embodiment described above.

First, as in the previously described embodiment, a semiconductor substrate W and a support substrate G are prepared by performing the processes shown in, for example, FIG. 3 and FIG. 4.

Then, as in the previously described embodiment, an adhesive layer Q is formed continuously on the first surface W1 and bevel portion WB of the semiconductor substrate W. Then, as shown in FIG. 5, the semiconductor substrate W having the adhesive layer Q formed continuously on the first surface W1 and bevel portion WB and a support substrate G having a peeling layer H formed thereon are bonded together so that the first surface W1 of the semiconductor substrate W and the third surface G1 of the support substrate G are bonded together via the adhesive layer Q.

Next, in this second modification, as shown in FIG. 11, for example, the fourth surface G2 of the support substrate G of the bonded structure WG is fixed to the stage T of the semiconductor manufacturing apparatus 200.

Then, the control unit CON of the semiconductor manufacturing apparatus 200 controls the rotational operation of the stage T while the semiconductor substrate W and the support substrate G are bonded together by the adhesive layer Q, and also controls the displacement and trimming operation of the trimming blade B.

In this second modification, as shown in FIG. 11, for example, with the semiconductor substrate W and the support substrate G bonded together by the adhesive layer Q, the support substrate G is fixed to the stage T and rotated while the trimming blade B is displaced in the X direction from the bevel portion WB side of the semiconductor substrate W toward the center of the semiconductor substrate W. As a result, at least the bevel portion WB and the portion of the adhesive layer Q formed on the bevel portion WB are ground by the trimming blade B.

Note that in this second modification as well, as shown in FIG. 3 already described, the second value d2 of the average diameter of the support substrate G is set to be smaller than the third value d3 of the average diameter of the region including the non-pattern forming region NA and the pattern region PA excluding the bevel portion WB of the semiconductor substrate W. This makes it possible to prevent the trimming blade B from coming into contact with the support substrate G when the trimming blade B is displaced in the X direction from the bevel portion WB side of the semiconductor substrate W toward the center of the semiconductor substrate W, as shown in FIG. 11. In other words, it is possible to make it easier to control the trimming blade B.

In this manner, as in the previously described embodiment, as shown in FIG. 8, at least the bevel portion WB and the portion of the adhesive layer Q formed on the bevel portion WB are removed from the semiconductor substrate W by trimming with the trimming blade.

Therefore, in the end region U near the non-pattern forming region NA of the semiconductor substrate W, the end of the adhesive layer Q is thicker to a certain extent compared to the thickness of the adhesive layer Q adhered to the bevel portion WB, so that peeling of the adhesive layer Q can be suppressed.

In other words, according to the method of manufacturing semiconductor device relating to the second modification, peeling of the peripheral portion of the adhesive that bonds the semiconductor substrate and the support substrate during the manufacturing process of the semiconductor device can be suppressed.

### Third Modification

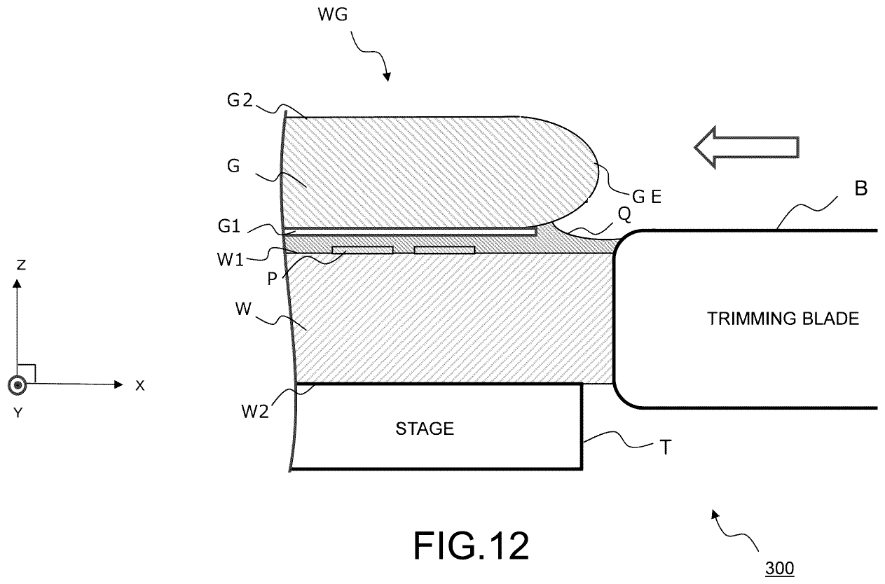

FIG. 12 is a cross-sectional view showing an example of a process for trimming a region including a bevel portion of a semiconductor wafer in a method of manufacturing semiconductor devices according to a third modification. The configuration of the semiconductor manufacturing apparatus 300 according to the third modification is the same as that of the semiconductor manufacturing apparatus 100 shown in FIG. 1 of the embodiment described above.

First, as in the previously described embodiment, a semiconductor substrate W and a support substrate G are prepared by, for example, performing the processes shown in FIG. 3 and FIG. 4.

Then, as in the previously described embodiment, an adhesive layer Q is formed continuously on the first surface W1 and bevel portion WB of the semiconductor substrate W. Then, as shown in FIG. 5, the semiconductor substrate W having the adhesive layer Q formed continuously on the first surface W1 and bevel portion WB and a support substrate G having a peeling layer H formed thereon are bonded together so that the first surface W1 of the semiconductor substrate W and the third surface G1 of the support substrate G are bonded together via the adhesive layer Q.

Next, in this third modification, for example, as shown in FIG. 12, the second surface W2 of the semiconductor substrate W of the bonded structure WG is fixed to the stage T of the semiconductor manufacturing apparatus 100.

Then, the control unit CON of the semiconductor manufacturing apparatus 100 controls the rotational operation of the stage T while the semiconductor substrate W and the support substrate G are bonded together by the adhesive layer Q, and also controls the displacement and trimming operation of the trimming blade B.

In this third modification, as shown in FIG. 12, for example, with the semiconductor substrate W and the support substrate G bonded together by the adhesive layer Q, the semiconductor substrate W is fixed to the stage T and rotated while the trimming blade B is displaced in the X direction from the bevel portion WB side of the semiconductor substrate W toward the center of the semiconductor substrate W. As a result, at least the bevel portion WB and the portion of the adhesive layer Q formed on the bevel portion WB are ground by the trimming blade B.

It is noted that in this third modification, as shown in FIG. 3 already described, the second value d2 of the average diameter of the support substrate G is set to be smaller than the third value d3 of the average diameter of the region including the non-pattern forming region NA and the pattern region PA excluding the bevel portion WB of the semiconductor substrate W. This makes it possible to prevent the trimming blade B from coming into contact with the support substrate G when the trimming blade B is displaced in the X direction from the bevel portion WB side of the semiconductor substrate W toward the center of the semiconductor substrate W, as shown in FIG. 12. In other words, it is possible to make it easier to control the trimming blade B.

In this manner, as in the previously described embodiment, as shown in FIG. 8, at least the bevel portion WB and the portion of the adhesive layer Q formed on the bevel portion WB are removed from the semiconductor substrate W by trimming with the trimming blade.

Therefore, in the end region U near the non-pattern forming region NA of the semiconductor substrate W, the thickness of the adhesive layer Q at the end is somewhat thicker than the thickness of the adhesive layer Q attached to the bevel portion WB, so peeling of the adhesive layer Q can be suppressed.

As described above, the method of manufacturing semiconductor devices according to the third modification can suppress peeling of the peripheral portions of the adhesive that bonds the semiconductor substrate and the support substrate during the manufacturing process of the semiconductor device.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A method of manufacturing a semiconductor device, comprising:
bonding a semiconductor substrate having a first surface including a pattern region in which a device pattern is provided, a second surface opposite to the first surface, and a bevel portion located on the periphery of the first surface and the second surface, and an adhesive layer formed continuously on the first surface and the bevel portion, to a support substrate having a third surface including a release layer region in which a release layer is formed, so that the first surface and the third surface are bonded via the adhesive layer; and
removing at least the bevel portion and a portion of the adhesive layer formed in the bevel portion from the semiconductor substrate, in a state the semiconductor substrate and the support substrate are bonded together with the adhesive layer.

2. The method of manufacturing semiconductor device according to claim 1, wherein the semiconductor substrate and the support substrate are bonded together such that a perpendicular line to the first surface of the semiconductor substrate, which passes through the center of the first surface, passes through the center of the third surface of the support substrate.

3. The method of manufacturing semiconductor device according to claim 2,
wherein the semiconductor substrate has an average diameter, in a direction parallel to the first surface of the semiconductor substrate, that is a first value,
wherein the support substrate has an average diameter, in a direction parallel to the third surface of the support substrate, that is a second value,
wherein the first value is greater than the second value, and
wherein the second value is greater than the distance of the pattern region in the direction parallel to the first surface.

4. The method of manufacturing a semiconductor device according to claim 3,
wherein the semiconductor substrate has an average diameter, excluding a bevel portion of the semiconductor substrate, in a direction parallel to the first surface of the semiconductor substrate, that is a third value. and
wherein the second value is smaller than the third value.

5. The method of manufacturing semiconductor device described in claim 1, wherein at least the bevel portion and the part of the adhesive layer formed on the bevel portion are removed from the semiconductor substrate by trimming with a trimming blade.

6. The method of manufacturing semiconductor device according to claim 5,
wherein,
when the bevel portion and the part of the adhesive layer formed on the bevel portion are removed from the semiconductor substrate, in a state in which the semiconductor substrate and the support substrate are bonded together by the adhesive layer,
at least the bevel portion and the part of the adhesive layer formed on the bevel portion are removed from the semiconductor substrate by trimming with the trimming blade while displacing the trimming blade from the second surface side toward the first surface side of the semiconductor substrate.

7. The method of manufacturing semiconductor device according to claim 5,
wherein,
when the bevel portion and the part of the adhesive layer formed on the bevel portion are removed from the semiconductor substrate, in a state in which the semiconductor substrate and the support substrate are bonded together with the adhesive layer,
at least the bevel portion and the part of the adhesive layer formed on the bevel portion are removed from the semiconductor substrate by trimming with the trimming blade while displacing the trimming blade from the first surface side toward the second surface side of the semiconductor substrate.

8. The method of manufacturing semiconductor device according to claim 5,
wherein,
when the bevel portion and the part of the adhesive layer formed on the bevel portion are removed from the semiconductor substrate, in a state in which the semiconductor substrate and the support substrate are bonded together with the adhesive layer,
at least the bevel portion and the part of the adhesive layer formed on the bevel portion are removed from the semiconductor substrate by trimming with the trimming blade in such a manner that the trimming blade is displaced from the bevel portion side of the semiconductor substrate toward the center of the semiconductor substrate.

9. The method of manufacturing semiconductor device according to claim 5, wherein, with the semiconductor substrate and the support substrate bonded together by the adhesive layer, at least the bevel portion and the portion of the adhesive layer formed on the bevel portion are simultaneously removed from the semiconductor substrate by trimming with the trimming blade.

10. A semiconductor manufacturing apparatus for manufacturing semiconductor devices, comprising:
a stage that fixes and rotates a bonded structure in which a semiconductor substrate and a support substrate are bonded;
a trimming blade that trims an end of the bonded structure; and
a control unit that controls a rotational operation of the stage and a displacement and trimming operation of the trimming blade,
wherein the semiconductor substrate has a first surface including a pattern region in which a device pattern is provided, a second surface opposite to the first surface, and a bevel portion located on the periphery of the first surface and the second surface, and an adhesive layer is formed continuously on the first surface and the bevel portion, and the support substrate has a third surface including a release layer region in which a release layer is formed, and
wherein,
in a state in which the semiconductor substrate and the support substrate are bonded together by the adhesive layer so that the first surface and the third surface are bonded together via the adhesive layer,
the control unit controls the rotational operation of the stage, and controls the displacement and trimming operation of the trimming blade to remove at least the bevel portion and the portion of the adhesive layer formed in the bevel portion from the semiconductor substrate by trimming with the trimming blade.

11. The semiconductor manufacturing apparatus according to claim 10, wherein the semiconductor substrate and the support substrate are bonded together such that a perpendicular line to the first surface of the semiconductor substrate, which passes through the center of the first surface, passes through the center of the third surface of the support substrate.

12. The semiconductor manufacturing apparatus according to claim 11,
wherein the semiconductor substrate has an average diameter, in a direction parallel to the first surface of the semiconductor substrate, that is a first value,
wherein the support substrate has an average diameter, in a direction parallel to the third surface of the support substrate, that is a second value,
wherein the first value is greater than the second value, and
wherein the second value is greater than the distance of the pattern region in the direction parallel to the first surface.

13. The semiconductor manufacturing apparatus according to claim 12,
wherein the semiconductor substrate has an average diameter, excluding a bevel portion of the semiconductor substrate, in a direction parallel to the first surface of the semiconductor substrate, that is a third value. and
wherein the second value is smaller than the third value.

14. The semiconductor manufacturing apparatus according to claim 10,
wherein,
when the bevel portion and the part of the adhesive layer formed on the bevel portion are removed from the semiconductor substrate, in a state in which the semiconductor substrate and the support substrate are bonded together by the adhesive layer,
at least the bevel portion and the part of the adhesive layer formed on the bevel portion are removed from the semiconductor substrate by trimming with the trimming blade while displacing the trimming blade from the second surface side toward the first surface side of the semiconductor substrate.

15. The semiconductor manufacturing apparatus according to claim 10,
wherein,
when the bevel portion and the part of the adhesive layer formed on the bevel portion are removed from the semiconductor substrate, in a state in which the semiconductor substrate and the support substrate are bonded together with the adhesive layer,
at least the bevel portion and the part of the adhesive layer formed on the bevel portion are removed from the semiconductor substrate by trimming with the trimming blade while displacing the trimming blade from the first surface side toward the second surface side of the semiconductor substrate.

16. The semiconductor manufacturing apparatus according to claim 10,
wherein,
when the bevel portion and the part of the adhesive layer formed on the bevel portion are removed from the semiconductor substrate, in a state in which the semiconductor substrate and the support substrate are bonded together with the adhesive layer,
at least the bevel portion and the part of the adhesive layer formed on the bevel portion are removed from the semiconductor substrate by trimming with the trimming blade in such a manner that the trimming blade is displaced from the bevel portion side of the semiconductor substrate toward the center of the semiconductor substrate.

17. The semiconductor manufacturing apparatus according to claim 10, wherein, with the semiconductor substrate and the support substrate bonded together by the adhesive layer, at least the bevel portion and the portion of the adhesive layer formed on the bevel portion are simultaneously removed from the semiconductor substrate by trimming with the trimming blade.
